(19) United States
(12) Patent Application Publication
(10) Pub. No.: US 2025/0331350 A1
(43) Pub. Date: Oct. 23, 2025

(54) DISPLAY SCREEN

(71) Applicant: Wuhan Tuopu Jingyan Semiconductor Technology Co. Ltd., Wuhan (CN)

(72) Inventors: Ying QIN, Wuhan (CN); Caiyun HE, Wuhan (CN)

(21) Appl. No.: 19/015,290

(22) Filed: Jan. 9, 2025

(30) Foreign Application Priority Data
Apr. 18, 2024 (CN) 202410466362.3

(51) Int. Cl. H10H 29/34; H10H 29/45

(52) U.S. Cl. CPC H10H 29/34; H10H 29/45

(57) ABSTRACT

The present disclosure relates to a display screen, comprising: a first CMOS circuit layer; a second CMOS circuit layer, located on the first CMOS circuit layer; a light emitting unit layer, located on a side of the second CMOS circuit layer away from the first CMOS circuit layer; the light emitting unit layer comprises a plurality of light emitting units, and the plurality of light emitting units correspond to pixel driving circuits of the first CMOS circuit layer and pixel driving circuits of the second CMOS circuit layer in a one-to-one correspondence; the first CMOS circuit layer comprises different types of CMOS devices than the second CMOS circuit layer. The present solution effectively improves the PPI of the display device, and reduces the size of the entire micro LED-on-silicon display device.

### CROSS REFERENCES TO RELATED APPLICATION

The present application claims priority to Chinese patent application No. 202410466362.3, titled “Display Screen”, and filed on Apr. 18, 2024, the content of which is hereby incorporated by reference in its entirety.

### TECHNICAL FIELD

The present disclosure relates to the field of display technology, and particularly to a display screen.

### BACKGROUND

A microdisplay-on-silicon is a special displayer that is based on silicon semiconductor technology, has a small physical size and can form a large field of view through optical amplification. The existing microdisplay-on-silicon generally includes a Complementary Metal-Oxide-Semiconductor (CMOS)-on-silicon drive circuit and a light emitting device. Both the micro Light Emitting Diode (LED) and the Organic Light-Emitting Diode (OLED) light emitting materials can be grown on the silicon to manufacture the microdisplay-on-silicon which can be applied to the currently popular near-eye display devices and virtual display devices. Because of its small size and high brightness, the Micro LED-on-silicon is recently widely studied as an optimum solution in the Augmented Reality (AR) display field. The small size is one pain point in the requirements of the Micro LED-on-silicon display module as the AR glasses application. Improvement of Pixels Per Inch (PPI) in a display area is an effective technical solution for implementing a small size. In the prior art, to improve the PPI of the Micro LED-on-silicon display device, the size of the Micro LED and the size of the CMOS-on-silicon pixel driving circuit need to be simultaneously reduced. However, the reduction of the size of the CMOS-on-silicon pixel driving circuit needs to be implemented through a high-precision process of a wafer factory, which causes a greater process difficulty and a higher manufacturing cost.

### SUMMARY

In view of this, as for the technical problem described above, it is necessary to provide a display screen, so that a higher pixel circuit density can be implemented without a need of a high-precision process, the Pixels Per Inch (PPI) of the display device is improved, and a size of the entire micro LED-on-silicon display device is reduced.

In some embodiment, a display screen is provided, including:
a first Complementary Metal-Oxide-Semiconductor (CMOS) circuit layer;
a second CMOS circuit layer, located on the first CMOS circuit layer;
a light emitting unit layer, located on a side of the second CMOS circuit layer away from the first CMOS circuit layer, the light emitting unit layer including a plurality of light emitting units, and the plurality of light emitting units correspond to pixel driving circuits of the first CMOS circuit layer and pixel driving circuits of the second CMOS circuit layer in a one-to-one correspondence;
the first CMOS circuit layer includes different types of CMOS devices than the second CMOS circuit layer.

In some embodiment, an intermediate CMOS circuit layer is provided between the light emitting unit layer and the second CMOS circuit layer, the intermediate CMOS circuit layer includes at least one combination of the first CMOS circuit layer and the second CMOS circuit layer stacked sequentially from bottom to top.

In some embodiment, the second CMOS circuit layer includes a Silicon-On-Insulator (SOI) device area and a conducting connection area configured to conduct upper and lower layer signals, and the SOI device area surrounds the conducting connection area.

In some embodiment, the second CMOS circuit layer includes:
a substrate;
a CMOS layer, located on the substrate, wherein the CMOS layer includes an SOI Negative channel-Metal-Oxide-Semicondutor (NMOS) device and an SOI Positive channel-Metal-Oxide-Semiconductor (PMOS) device, a shallow trench isolation structure is provided between the SOI NMOS device and the SOI PMOS device, the conducting connection area is located in the shallow trench isolation structure between the SOI NMOS device and the SOI PMOS device;
a first metal interconnection layer, located on the CMOS layer.

In some embodiment, the first metal interconnection layer includes a plurality of sub-metal layers stacked sequentially.

In some embodiment, the first CMOS circuit layer includes:
a substrate;
an epitaxial layer, located on the substrate and including a bulk CMOS device.

In some embodiment, the bulk CMOS device includes:
a CMOS layer, including a PMOS device located in an N-well and an NMOS device located in a P-Well, a Shallow Trench Isolation (STI) structure being provided between the PMOS device and the NMOS device;
a second metal interconnection layer, located on the CMOS layer.

In some embodiment, the the second metal interconnection layer includes a plurality of sub-metal layers stacked sequentially.

In some embodiment, the second CMOS circuit layer includes one or more second CMOS device sub-layers stacked sequentially.

In some embodiment, the first CMOS circuit layer includes a bulk CMOS device, and the second CMOS circuit layer includes an SOI CMOS device.

In order to resolve the aforementioned problem, the present disclosure provides a display screen, in which a plurality of second CMOS circuit layers and first CMOS circuit layers based on different types of CMOS devices are stacked under the light emitting unit layer, so that a three-dimensional integrated stack structure is formed. Accordingly, a higher pixel circuit density can be implemented without using a high-precision process of a wafer factory, thereby effectively improving the PPI of the display device, and reducing the size of the entire micro LED-on-silicon display device.

The above description is merely an overview of the technical solution of the present disclosure. In order to better understand the technical means of the present disclosure and implement the present disclosure according to the content of the specification, the present disclosure will be elaborated below in combination with the preferred embodiments of the present disclosure with reference to the accompanying drawings.

### BRIEF DESCRIPTION OF THE DRAWINGS

In order to describe the technical solution in the embodiments of the present disclosure more clearly, the accompanying drawings required for describing the embodiments will be briefly introduced. Obviously, the accompanying drawings in the following description are merely some embodiments of the present disclosure, and a person of ordinary skill in the art may still obtain other drawings from these accompanying drawings without creative efforts.

FIG. 1 is a schematic structure diagram of a display screen according to an embodiment of the present disclosure.

FIG. 2 is a schematic structure diagram of a display device according to an embodiment of the present disclosure.

FIG. 3 is a schematic diagram of a relative position relationship of a stack structure of a display device according to an embodiment of the present disclosure.

FIG. 4 is a schematic diagram of a Bulk CMOS manufactured based on a Si substrate according to an embodiment of the present disclosure.

FIG. 5 is a schematic structure diagram of a Bulk CMOS according to an embodiment of the present disclosure.

FIG. 6 is a schematic diagram of a three-dimensional stack structure of a display screen according to an embodiment of the present disclosure.

FIG. 7 is a schematic diagram of a multi-layer stack structure of a display screen according to an embodiment of the present disclosure.

### REFERENCE SIGNS

11, light emitting unit layer; 12, second CMOS circuit layer; 13, first CMOS circuit layer; 14, peripheral circuit; 15, pixel driving circuit; 16, intermediate circuit layer; 121, SOI device area; 122, conducting connection area.

### DETAILED DESCRIPTION

For ease of understanding the present disclosure, the present disclosure will be comprehensively described with reference to related accompanying drawings. Preferred embodiments of the present disclosure are provided in the accompanying drawings. However, the present disclosure may be implemented in many different forms, and is not limited to the embodiments described herein. Rather, these embodiments are provided to make the disclosure more thorough and comprehensive.

Unless otherwise defined, all technical and scientific terms used herein have the same meaning as those commonly understood by persons skilled in the technical field of the present disclosure. The terms used in the specification of the present disclosure are merely intended to describe specific embodiments, and are not intended to limit the present disclosure. The term “and/or” as used herein may include any and all combinations of one or more associated listed items.

It should be appreciated that when an element or a layer is referred to as being “on”, “ ” adjacent to”, “connected to” or “coupled with” another element ot layer, it may be directly provided on, or adjacent to, or connected to, or coupled with another element or layer; or there may exist an intermediate element or layer. Instead, when the element is referred to as being “directly on”, “directly adjacent to”, “directly connected to”, or “directly coupled with” another element or layer, there is no intermediate element or layer. It should be appreciated that, although the terms “first”, “second”, “third” and the like may be utilized to describe various elements, components, areas, layers and/or portions, these elements, components, areas, layers and/or portions shall not be limited by these terms. These terms are only utilized to distinguish one element, component, area, layer or portion from another. Therefore, without departing from the teaching of the present disclosure, the first element, component, area, layer or portion discussed below may represent the second element, component, area, layer or portion.

The spatial relationship terms “under”, “below”, “lower”, “beneath”, “above”, “upper”, etc., may be used herein for convenience of description, in order to describe a relationship between one element or feature shown and another element or feature in the figures. It should be understood that, in addition to the orientations shown in the figures, the spatial relationship term intention may further include different orientations of devices in use and operation. For example, when a device in the figure is turned over, the element or feature described as being “under”, “below” or “beneath” another element or feature is oriented to be “above” another element or feature. Thus, the exemplary terms “under” and “below” may include two orientations: upper and lower. The device may be otherwise oriented (rotated by 90 degrees or other orientations) and the spatial descriptors used herein are interpreted accordingly.

The terms used herein are intended only to describe specific embodiments and are not intended to limit the present disclosure. In use herein, “a”, “one”, and “the” in the single form are also intended to include the plural form unless the context clearly indicates another manner. It should also be understood that the terms “consisting of” and/or “including” are used in the specification to determine the existence of features, integers, steps, operations, elements and/or components, but not exclude the existence and addition of one or more other features, integers, steps, operations, elements, components and/or groups. When use herein, the term “and/or” may include any and all combinations of the items listed.

The disclosed embodiments are described herein with reference to a cross-sectional view which is a schematic diagram of an embodiment (and an intermediate structure) of the present disclosure. In such a manner, a change from the shown shape due to, for example, manufacturing technology and/or tolerance may be predicted. Therefore, the embodiments of the present disclosure should not be limited to a specific shape of the area shown herein, but may include a shape deviation due to, for example, the manufacturing. The areas shown in the figures are essentially exemplary, shapes thereof are not intended to display actual shapes of the areas on the chip, and are not intended to limit the scope of the present disclosure.

The present disclosure provides a display screen, which may be a micro LED-on-silicon display device having a three-dimensional integrated stack structure.

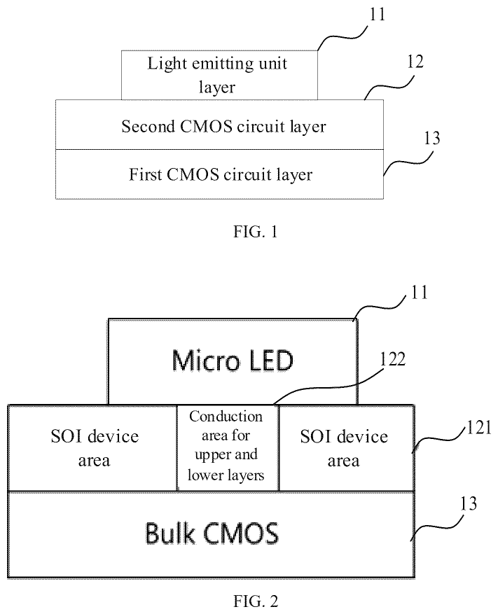

As shown in FIG. 1, the display screen may include a first CMOS circuit layer 13, a second CMOS circuit layer 12, and a light emitting unit layer 11, which are stacked from bottom to top. The second CMOS circuit layer 12 is located on the first CMOS circuit layer 13. The light emitting unit layer 11 is located on a side of the second CMOS circuit layer 12 away from the first CMOS circuit layer 13. Specifically, the light emitting unit layer 11 includes a plurality of light emitting units. The plurality of light emitting units correspond to pixel driving circuits of the first CMOS circuit layer 13 and pixel driving circuits of the second CMOS circuit layer 12 in a one-to-one correspondence. The first CMOS circuit layer 13 may include different types of CMOS devices than the second CMOS circuit layer 12.

In some examples of the embodiment, the first CMOS circuit layer may include a Bulk CMOS device. The second CMOS circuit layer may include a silicon-on-insulator (SOI) CMOS device.

Specifically, the first CMOS circuit layer may be a CMOS circuit manufactured by a bulk silicon process. The second CMOS circuit layer may be a CMOS circuit manufactured by an SOI process.

In some examples of the embodiment, the second CMOS circuit layer may include an SOI device area and a conducting connection area configured to conduct upper and lower layer signals. The SOI device area surrounds the conducting connection area.

Specifically, as shown in FIG. 2, the light emitting unit layer 11 may be a micro LED device. The bulk CMOS corresponding to the first CMOS circuit layer 13 is manufactured by using a bulk Si CMOS process. The second CMOS circuit layer 12 (SOI CMOS layer) located in the middle position may include an SOI device area 121 and a conducting connection area 122 for the upper and lower layer signals. The SOI CMOS circuit layer, due to the SOI process structure characteristic thereof, can be thinned to a thickness of an effective film layer. For example, the effective film layer may include a buried oxide layer, an active layer, and a metal interconnection layer. The thickness of the effective film layer may be in a range of 1 μm to 99 μm. Therefore, the effective film layer is also adapted to serve as an intermediate layer configured to provide signal conducting connection for two layers of CMOS devices and signal conducting connection between a bottom-layer bulk CMOS device and a top-layer micro LED device.

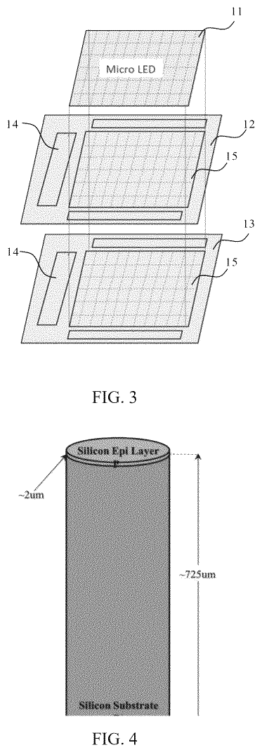

In addition, the top-layer micro LED may be a micro LED having a vertical structure or a Flip-chip structure, etc. Referring to FIG. 3, both the first CMOS circuit layer 13 and the second CMOS circuit layer 12 may include corresponding pixel driving circuits 15 and a peripheral circuit 14. Each micro LED in the light emitting unit layer 11 is in a one-to-one correspondence with a pixel driving circuit 15 of each lower layer.

In some examples of the embodiment, the first CMOS circuit layer may include a substrate and an epitaxial layer. The epitaxial layer is located on the substrate, and the epitaxial layer includes a bulk CMOS device.

In some examples of the embodiment, the bulk CMOS device may include a CMOS layer and a second metal interconnection layer. The CMOS layer may include a Positive channel-Metal-Oxide-Semiconductor (PMOS) device located in an N-well and a Negative channel-Metal-Oxide-Semicondutor (NMOS) device located in a P-Well. A shallow trench isolation (STI) structure is provided between the PMOS device and the NMOS device. The second metal interconnection layer is located on the CMOS layer.

In some examples of the embodiment, the second CMOS circuit layer may include one or more second CMOS device sub-layers stacked sequentially.

As an example, referring to FIG. 4, the lower second CMOS circuit layer may be a bulk CMOS layer manufactured by the bulk Si process, the CMOS device circuit of the lower second CMOS circuit layer is manufactured on the epitaxial layer of a surface of the silicon substrate (i.e., silicon Epi layer) (2 μm), and a total thickness of the substrate (i.e., silicon substrate) is about 725 μm.

Referring to FIG. 5, the PMOS device and the NMOS device of the bulk CMOS are respectively manufactured in the N-well and the P-Well. If the silicon substrate itself has P+ doping, the NMOS device may be directly manufactured on the silicon substrate, and there is no need to perform the P+ doping on the silicon substrate to form the P-well. The PMOS device is isolated from the NMOS device by means of the shallow trench isolation structure STI. After the bulk CMOS device is completely manufactured, the metal interconnection layer is manufactured on the bulk CMOS device. After the bulk silicon CMOS process (including a front-end process and a back-end process) of Norma is completed, a top-layer metal pad is reserved as an anode pad configured to be connected to an LED and as an interface pad configured to be connected to an upper-layer SOI circuit module.

In some examples of the embodiment, the second metal interconnection layer may include a plurality of sub-metal layers stacked sequentially.

After the bulk CMOS device is completely manufactured, a number of metal interconnection layers are manufactured on the bulk CMOS device, generally, 2 to 10 metal interconnection layers, to form interconnections among signals of devices. For example, 2, 5, 7, 8, and 10 sub-metal layers are adopted.

In some examples of the embodiment, the second CMOS circuit layer may include a substrate, a CMOS layer, and a first metal interconnection layer. The CMOS layer is located on the substrate, and includes an SOI NMOS device and an SOI PMOS device. A shallow trench isolation structure is provided between the SOI NMOS device and the SOI PMOS device. The conducting connection area is located in the shallow trench isolation structure between the SOI NMOS device and the SOI PMOS device. The first metal interconnection layer is located on the CMOS layer.

As an example, the SOI CMOS circuit of the intermediate layer may include an SOI device area and a conducting connection area for upper and lower-layer signals. The conducting connection area may be manufactured in the STI area between the SOI NMOS device and the PMOS device, to avoid the SOI device area, in order to avoid affecting the performance of the SOI CMOS device. After the SOI CMOS device is completely manufactured, the metal interconnection layer is manufactured on the SOI CMOS device.

Similarly, a number of metal interconnection layers are then manufactured on the SOI CMOS device, generally about 2 to 10 layers, to form an interconnection among signals of devices and a signal connection to the lower-layer bulk CMOS device, and a signal that finally drives the micro LED is connected to a metal through hole or a metal pad of the top layer.

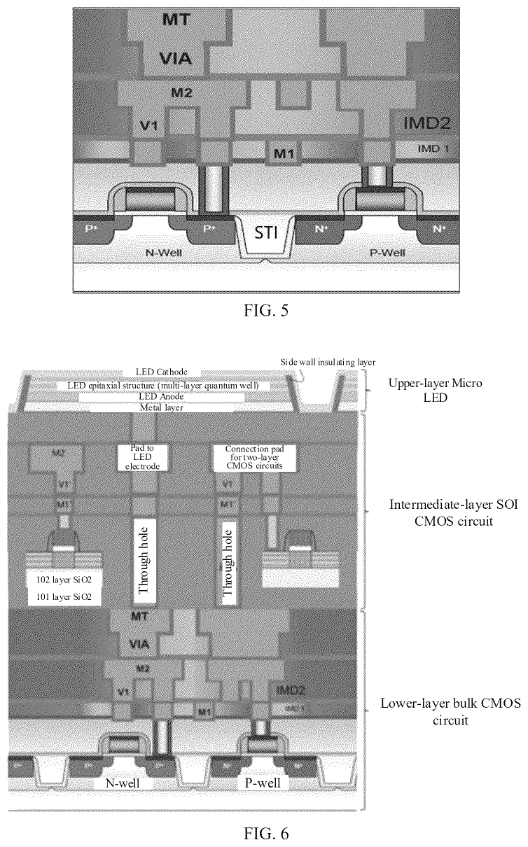

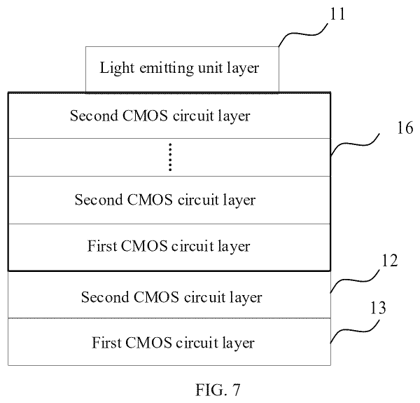

The upper-layer micro LED light emitting device layer may have a micro LED device structure such as a vertical structure, or may have a Flip-chip structure or other structure types according to application requirements. Referring to FIG. 6, the upper-layer micro LED light emitting device may include a metal layer, an LED anode, an LED epitaxial structure (such as a multi-layer quantum well), and an LED cathode from bottom to top. Electrodes of the micro LED device can be connected, by means of the metal conducting pad of the SOI layer, to a signal line of the lower-layer driver circuit configured to control the emission of the LED device.

In some examples of this embodiment, the first metal interconnection layer may include a plurality of sub-metal layers stacked sequentially.

As an example, after the SOI CMOS device is completely manufactured, a metal interconnection layer is manufactured on the SOI CMOS device. Similarly, a number of metal interconnection layers are then manufactured on the SOI CMOS device, generally about 2 to 10 layers, to form the interconnection among the signals of the devices and a signal connection to the lower-layer bulk CMOS device, and the signal that finally drives the micro LED device is connected to a metal through hole or a metal Pad of the top layer.

In some examples of the embodiment, an intermediate CMOS circuit layer is provided between the light emitting unit layer and the second CMOS circuit layer. The intermediate CMOS circuit layer may include at least one combination of the first CMOS circuit layer and the second CMOS circuit layer stacked sequentially from bottom to top.

Specifically, the CMOS integrated device structure including at least two layers may be stacked, including at least one CMOS circuit layer manufactured by the bulk silicon process and at least one CMOS circuit layer manufactured by the SOI process. For example, the structure may include two second CMOS circuit layers and two first CMOS circuit layers, specifically including a first CMOS circuit layer, a second CMOS circuit layer, a first CMOS circuit layer, a second CMOS circuit layer, and a light emitting unit layer sequentially stacked from bottom to top.

The display screen provided in the present disclosure is a micro LED-on-silicon display device having a three-dimensional integrated stack structure. The CMOS integrated device circuit structure including at least two layers may implement a high pixel circuit density without using a high-precision process of a wafer factory, thereby effectively improving the PPI of the display device, and reducing a size of the entire micro LED-on-silicon display device. In addition, the use of wafer factory process with lower precision may also improve a production yield of a wafer CMOS backplane to a certain extent.

It should be noted that the abovementioned embodiments are for illustrative purposes only and are not intended to limit the present disclosure.

It should be appreciated that, unless explicitly stated in the specification, steps are not performed in a strict order, and these steps may be performed in other orders. In addition, at least a part of the steps in the manufacturing process may include multiple sub-steps or multiple stages. These sub-steps or stages are not definitely performed at the same moment, but may be performed at different moments. These sub-steps or stages are also not definitely performed sequentially, but may be performed in turns or alternately with at least a part of other steps, or sub-steps or stages of other steps.

The embodiments in the present disclosure are described in a progressive manner. Each embodiment focuses on a difference from other embodiments. For the same or similar part of the embodiments, reference can be made to each other.

The technical limitations in the above embodiments can be combined in any manner. In order to make the description concise, all possible combinations of the technical limitations in the above embodiments are not described. However, as long as there is no contradiction in the combination of these technical limitations, these combinations are considered to fall within the scope of the present disclosure.

What is claimed is:

1. A display screen, comprising:
a first Complementary Metal-Oxide-Semiconductor (CMOS) circuit layer;
a second CMOS circuit layer, located on the first CMOS circuit layer; and
a light emitting unit layer, located on a side of the second CMOS circuit layer away from the first CMOS circuit layer, wherein the light emitting unit layer comprises a plurality of light emitting units, and the plurality of light emitting units correspond to pixel driving circuits of the first CMOS circuit layer and pixel driving circuits of the second CMOS circuit layer in a one-to-one correspondence;
wherein the first CMOS circuit layer comprises different types of CMOS devices than the second CMOS circuit layer.

2. The display screen according to claim 1, wherein an intermediate CMOS circuit layer is provided between the light emitting unit layer and the second CMOS circuit layer, and the intermediate CMOS circuit layer comprises at least one combination of the first CMOS circuit layer and the second CMOS circuit layer stacked sequentially from bottom to top.

3. The display screen according to claim 1, wherein the second CMOS circuit layer comprises a Silicon-On-Insulator (SOI) device area and a conducting connection area configured to conduct upper and lower layer signals, and the SOI device area surrounds the conducting connection area.

4. The display screen according to claim 1, wherein the second CMOS circuit layer comprises:
a substrate;
a CMOS layer, located on the substrate, wherein the CMOS layer comprises an SOI Negative channel-Metal-Oxide-Semicondutor (NMOS) device and an SOI Positive channel-Metal-Oxide-Semiconductor (PMOS) device, a shallow trench isolation structure is provided between the SOI NMOS device and the SOI PMOS device, and the conducting connection area is located in the shallow trench isolation structure between the SOI NMOS device and the SOI PMOS device; and
a first metal interconnection layer, located on the CMOS layer.

5. The display screen according to claim 1, wherein the first metal interconnection layer comprises a plurality of sub-metal layers stacked sequentially.

6. The display screen according to claim 1, wherein the first CMOS circuit layer comprises:
a substrate;
an epitaxial layer, located on the substrate and comprising a bulk CMOS device.

7. The display screen according to claim 6, wherein the bulk CMOS device comprises:
a CMOS layer, comprising a PMOS device located in an N-well and an NMOS device located in a P-Well, a Shallow Trench Isolation (STI) structure being provided between the PMOS device and the NMOS device; and
a second metal interconnection layer, located on the CMOS layer.

8. The display screen according to claim 7, wherein the the second metal interconnection layer comprises a plurality of sub-metal layers stacked sequentially.

9. The display screen according to claim 7, wherein the second CMOS circuit layer comprises one or more second CMOS device sub-layers stacked sequentially.

10. The display screen according to claim 1, wherein the first CMOS circuit layer comprises a bulk CMOS device, and the second CMOS circuit layer comprises an SOI CMOS device.
